(19) United States
(12) Patent Application Publication
(10) Pub. No.: US 2010/0087067 A1
(43) Pub. Date: Apr. 8, 2010

(54) METHOD FOR PACKAGING SEMICONDUCTOR

(76) Inventors: Joon-Mo Seo, Gyeonggi-do (KR); Byoung-Un Kang, Gyeonggi-do (KR); Kyung-Tae Wi, Gyeonggi-do (KR); Jae-Hoon Kim, Seoul (KR); Tae-Hyun Sung, Seoul (KR); Soon-Young Hyun, Gyeonggi-do (KR)

Correspondence Address: LADAS & PARRY LLP, 224 SOUTH MICHIGAN AVENUE, SUITE 1600, CHICAGO, IL, 60604, US

(21) Appl. No.: 12/523,560

(22) PCT Filed: Oct. 25, 2007
(86) PCT No.: PCT/KR2007/005272

§ 371 Date: Jul. 17, 2009

(30) Foreign Application Priority Data
Jan. 19, 2007 (KR) 10-2007-0005990

(51) Int. Cl. H01L 21/3205

(52) U.S. Cl. 438/758; 257/E21.294

(57) ABSTRACT

A method for packaging a semiconductor is provided to allow uniform coating of a die attachment paste, shorten a B-staging time, and improve die pick-up characteristics and die attachment characteristics. This method includes preparing a die attachment paste with a viscosity of 1,500 to 100,000 cps; rotating a wafer and applying the die attachment paste to an upper surface of the wafer into a predetermined thickness; and B-staging the paste applied on the wafer. This method makes it possible to reduce costs by substituting for WBL (Wafer Backside Lamination) film, uniformly apply a die attachment paste to a wafer, freely control a thickness of applied die attachment paste by adjusting viscosity and dosage of discharged paste and a speed of a spin coater, and also shorten a process time by decreasing a B-staging time.

### TECHNICAL FIELD

The present invention relates to a method for packaging a semiconductor, and more particularly to a method for packaging a semiconductor, which may allow uniform coating of a die attachment paste, shorten a B-staging time, and improve die pick-up characteristics and die attachment characteristics.

### BACKGROUND ART

In a semiconductor packaging process, a solvent-free or solvent-contained liquid, a liquid paste or a solid film are representatively used as a suitable adhesive. The solid film shows good workability, and it advantageously shows no or minimal bleeding against heat and pressure during the die attachment process. In addition, the solid film is advantageous in that a bondline, namely the tilt of a chip and the thickness of an adhesive existing in an interface between the chip and PCB may be easily controlled after the die attachment process.

In a conventional semiconductor packaging process using a liquid paste adhesive, dispensing is used for the coating process in case the paste is cured from A stage directly to C stage. This coating method does not allow uniformly controlling thickness and area of the paste. Thus, this method is not suitable for applying a thick paste between a chip and PCB. Meanwhile, in case a paste is cured from A stage through B stage to C stage, screen printing is used for the coating process. This screen printing is advantageous in controlling thickness and area of a paste to be applied, but it is disadvantageous since the thickness of paste applied onto PCB is irregularly controlled rather than an adhesive with a solid film form. In addition, the irregular thickness of the liquid paste is maintained after the B stage, so it may cause a tilt between the chip and the PCB during the die attachment process. Also, the melt flow phenomenon that causes leakage of paste out of the chip may also become worse. In case of the B-staging type paste used in a conventional packaging process, heat is mainly used for the B-staging process. Thus, a semiconductor should be exposed to high temperature and heat for a long time during the process, so PCB warpage may happen, which may cause inferiority during the chip attachment process after the B-staging process.

### DISCLOSURE OF INVENTION

### Technical Problem

Therefore, many endeavors for solving the above problems have been continuously made in the related art, and the present invention is designed under such a technical environment.

The present invention is directed to uniformly applying a paste to a wafer during a semiconductor packaging process, shortening a process time by reducing the time required for B-staging, and also preventing generation of warpage of PCB and wafer, and an object of the present invention is to provide a method for packaging a semi-conductor, which may accomplish the above issues.

### TECHNICAL SOLUTION

In order to accomplish the above object, the present invention provides a method for packaging a semiconductor, which includes preparing a die attachment paste with a viscosity of 1,500 to 100,000 cps; rotating a wafer and applying the die attachment paste to an upper surface of the wafer into a predetermined thickness; and B-staging the paste applied on the wafer.

The B-staging step may be conducted in a way of thermally drying the applied paste at 40 to 200° C.; thermally drying the applied paste at 40 to 200° C. and then irradiating ultraviolet (UV) thereto in 100 mJ/cm² to 6 J/cm² based on a UV A region; or firstly thermally drying the applied paste at 40 to 200° C., then irradiating ultraviolet (UV) thereto in 100 mJ/cm² to 6 J/cm² based on a UV A region, and then secondly thermally drying the wafer at 40 to 200° C. In addition, the B-staging step may be conducted in a way of irradiating UV to the applied paste in 100 mJ/cm² to 6 J/cm² based on a UV A region; or irradiating UV to the applied paste in 100 mJ/cm² to 6 J/cm² based on a UV A region and then thermally drying the paste at 40 to 200° C. after the UV irradiating step.

### BEST MODE FOR CARRYING OUT THE INVENTION

Hereinafter, preferred embodiments of the present invention will be described in detail with reference to the accompanying drawings. Prior to the description, it should be understood that the terms used in the specification and the appended claims should not be construed as limited to general and dictionary meanings, but interpreted based on the meanings and concepts corresponding to technical aspects of the present invention on the basis of the principle that the inventor is allowed to define terms appropriately for the best explanation.

In a method for packaging a semiconductor according to the present invention, first, a die attachment paste with a viscosity of 1,500 to 100,000 cps is prepared. The die attachment paste may employ any paste commonly used for die attachment. Representatively, the die attachment paste includes epoxy, acrylate, flexing agent, UV initiator, organic filler, and a dispersion solvent for the organic filler such as a co-solvent in which volatile solvent and reactant diluent are mixed, or a solvent containing only a reactant diluent. Regarding the numerical range related to the viscosity of the die attachment paste, if the viscosity is less than the lower limit, it is difficult to apply the paste over a thickness of 20 micrometers. Meanwhile, if the viscosity exceeds the upper limit, an amount of diluent and other solvents is relatively increased, which demands increased temperature, time and irradiation of heat or UV for removing or B-staging the diluent or other solvents. In addition, the problems in the B-staging also give bad influences on reliability of the entire product to which the paste is applied. Also, if the viscosity exceeds the upper limit, the thickness of the applied paste may be seriously deviated between a wafer center and a water end or inside. Furthermore, the variation of thickness may cause problems of melt flow, void, and die crack during the die attachment process, and also it may give bad influence on the reliability.

Then, the die attachment paste is applied onto a wafer using a spin coater into a pre-determined thickness. The thickness of the applied paste may be controlled in a way of adjusting viscosity and amount of the applied paste and a speed of the spin coater. Since the die attachment paste is applied to the wafer using the spin coater, the paste may be applied in a uniform thickness.

Then, the paste applied to the wafer is B-staged. In this step, the applied paste may be thermally dried at 40 to 200° C. Also, in this step, after being thermally dried at 40 to 200° C., the applied paste may progress to a UV irradiation process at 100 mJ/cm² to 6 J/cm² based on a UV A region. Also, after being thermally dried at 40 to 200° C., the applied paste may progress to a process of irradiating UV to the applied paste at 100 mJ/cm² to 6 J/cm² based on a UV A region and secondarily thermally drying the paste at 40 to 200° C. In addition, the B-staging step may progress to a UV irradiation process at 100 mJ/cm² to 6 J/cm² based on a UV A region, and it may also progress to a process of secondarily thermally drying the applied paste at 40 to 200° C. after irradiating UV thereto at 100 mJ/cm² to 6 J/cm² based on a UV A region.

The thermal drying process removes residual volatile components in a liquid paste and dissolves the thermal initiator into radicals or ions for reaction with reactants. The reaction conducted by the thermal initiator is not a full curing reaction, but the paste should be kept in a semi-curing state so as to allow die attachment after the thermal drying process. The paste in a semi-curing state keeps the liquid paste in a uniform thickness, minimize thickness reduction of the paste during the die attachment process, and prevent undesired contamination on PCB caused by melt-flow of the paste. In addition, during a wire-bonding process and an epoxy-molding process, the semi-curing paste keeps an adhesive force between the paste and the die or between the paste and the PCB over a certain level and also prevents deformation of the adhered state. If the paste does not reach a semi-curing state of a certain level even after the thermal drying process of the liquid paste, higher heat or more time may be required to solve this problem. However, it may result in warpage of PCB, which may give a bad influence on die attachment and reliability. Thus, to solve the above problems, the B-staging process using UV irradiation is conducted. The UV irradiation process advantageously allows a surface temperature of the irradiated product to be controlled to 100° C. or below through a product color, surroundings and some cooling devices. In addition, if dosage and intensity of UV used for the UV irradiation process are controlled, the time taken for the process may be shortened as much as a several tenth to several hundredth rather than the thermal heating process. Meanwhile, for using the UV irradiation process, UV initiator and UV reactant should be present in the liquid paste. In order to conduct B-staging only using the UV irradiation process without the thermal drying process, differently from the former processes, high heat should not be generated, so volatile solvent in the liquid paste should be restrained to the minimum. For this purpose, it may be advantageous to use only a reactive solvent rather than the co-solvent structure, and it is also more advantageous to use a reactive solvent that may keep a semi-curing state by means of UV irradiation. On occasions, the thermal drying process may be additionally conducted after UV irradiation. In this case, if phase separation occurs since the paste is exposed to an environment with much moisture or the semi-curing state is unstable, the thermal drying process is conducted to remove moisture and also keep the semi-curing state more stably. In the above five kinds of B-staging methods, the thermal drying process (including a first thermally drying and a second thermal drying) is preferably conducted for 1 second to 1 hour for better drying efficiency and prevention of warpage.

In case of the process for applying a paste directly to a wafer and then conducting B-staging thereto, the B-staging may be applied to a thermal drying process only when the B-staging is conducted within a short time at a lowest temperature together with preventing warpage inferiority of the wafer. For this purpose, a solvent in the paste employs a material with a low boiling point and a low vapor pressure, or a reactive solvent that ensures good reaction even at a low temperature though it has a high boiling point and a high vapor pressure. The former solvent should be contained in a sealed container for stability of the liquid since its volatility may be too good at normal temperature and normal pressure. In this way, B-staging may be conducted to the paste applied to a rear surface of the wafer by spin coating without damaging the wafer even though a thermal drying process is conducted at a low temperature within a short time. In addition, in case of B-staging using UV, the temperature at a UV-irradiated surface may be lowered to the minimum by reducing the dosage of infrared in the irradiated UV to the minimum. In a current technique using the above method, a dosage of infrared in comparison to generated UV may be reduced lower than 20% by changing an electrode type of a UV lamp from an arc-discharging type to a microwave type, and also a reflector may be also be treated to resist ultraviolet such that a dosage of generated infrared is minimized. Accordingly, though a high energy of 100 mJ/cm² to 6 J/cm² is irradiated based on a UV A region, the temperature of the irradiated surface may be controlled to 60° C. or below, and the process time may be relatively shortened into the range from 1 second to several minutes.

In relation to the numerical range of the thermal drying temperature, if the temperature is less than the lower limit, the paste may be very deficient in semi-curing state since the thermal treatment temperature is too low. In addition, since an amount of residual solvent is so great, there may occur irregular thickness of paste and melt-flow during a following die attachment process, and generation of voids in paste during a curing process. If the thermal drying temperature exceeds the upper limit, the thermal drying temperature is so high to cause warpage of the wafer and rapidly increase a volatilizing speed of solvent in the applied paste, which may generate a large amount of big voids in the surface and inside of the paste.

In relation to the numeral range of the UV region, if the UV region is less than the lower limit, an initiating effect of the initiator is deteriorated, so an amount of generated radicals and ions is decreased and reaction with the reactant is delayed. In this reason, the semi-curing state is deficient during the die attachment process, which may cause melt-flow or generation of voids in the paste during the curing process and also give an influence on reliability later. Meanwhile, if the UV region exceeds the upper limit, the initiator gives an excessive initiating effect, causing rapid increase of reaction. In addition, the liquid paste is changed from a semi-curing state to a full-curing state, which may cause inferior adhesion or die crack during the following die attachment process.

Then, the steps of laminating a dicing tape on the B-staged surface of the paste, sawing the wafer, picking up the die and attaching the die are executed. The dicing tape lamination step and the wafer sawing step may employ any processes commonly used in the conventional semiconductor packaging method. Also, the step of laminating a dicing tape on the B-staged surface of the paste is preferably conducted with a temperature in the range from a room temperature to 100° C. and a pressure of 0.5 to 20 kgf/□.

### MODE FOR THE INVENTION

Hereinafter, specific embodiments of the present invention are explained in more detail for better understanding. However, the embodiments of the present invention may be modified in various ways, and they do not limit the scope of the invention. The embodiments of the present invention are given only for those having ordinary skill in the art to understand the invention more perfectly.

### Embodiment 1

Liquid epoxy, solid epoxy, acrylic reactants, inorganic/organic filler, additives, thermal curing agent, thermal initiator, UV initiator, reactant solvent, and volatile solvent were mixed and made into a die attachment paste with a viscosity of 1,500 cps at a room temperature using a spindle with a rotation speed of 1 rpm. The prepared die attachment paste was applied to an upper portion of a wafer that was rotating by a spin coater. The paste applied to the wafer was thermally dried at 60° C. for 1 hour, and then UV was irradiated thereto at 6 J/□ based on the UV A region and MT lamination was conducted thereto at a room temperature. A ratio of thickness to diameter of the wafer used in the embodiment 1 was 12.5 □/inch.

### Embodiment 2

Liquid epoxy, solid epoxy, acrylic reactants, inorganic/organic filler, additives, thermal curing agent, thermal initiator, UV initiator, reactant solvent, and volatile solvent were mixed and made into a die attachment paste with a viscosity of 10,000 cps at a room temperature using a spindle with a rotation speed of 1 rpm. The prepared die attachment paste was applied to an upper portion of a wafer that was rotating by a spin coater. The paste applied to the wafer was thermally dried at 140° C. for 5 minutes, then UV was irradiated thereto at 3 J/□ based on the UV A region, and then the paste was thermally dried at 140° C. for 5 minutes again. After that, MT lamination was conducted thereto at a room temperature. The wafer used in the embodiment 2 was identical to that of the embodiment 1.

### Embodiment 3

Liquid epoxy, solid epoxy, acrylic reactants, inorganic/organic filler, additives, thermal curing agent, thermal initiator, UV initiator, reactant solvent, and volatile solvent were mixed and made into a die attachment paste with a viscosity of 100,000 cps at a room temperature using a spindle with a rotation speed of 1 rpm. The prepared die attachment paste was applied to an upper portion of a wafer that was rotating by a spin coater. UV was irradiated to the paste applied to the wafer at 150 J/□ based on the UV A region, then the paste was thermally dried at 180° C. for 10 seconds again, and then MT lamination was conducted thereto at a room temperature. The wafer used in the embodiment 3 was identical to that of the embodiment 1.

### Comparative Example 1

Liquid epoxy, solid epoxy, acrylic reactants, inorganic/organic filler, additives, thermal curing agent, thermal initiator, UV initiator, reactant solvent, and volatile solvent were mixed and made into a die attachment paste with a viscosity of 10,000 cps at a room temperature using a spindle with a rotation speed of 1 rpm. The prepared die attachment paste was applied to an upper portion of a wafer by means of screen printing. The paste applied to the wafer was thermally dried at 100° C. for 1 hour and 20 minutes, and then MT lamination was conducted thereto at a room temperature. A ratio of thickness to diameter of the wafer used in the comparative example 1 was 50 □/inch.

### Comparative Example 2

Liquid epoxy, solid epoxy, acrylic reactants, inorganic/organic filler, additives, thermal curing agent, thermal initiator, UV initiator, reactant solvent, and volatile solvent were mixed and made into a die attachment paste with a viscosity of 10,000 cps at a room temperature using a spindle with a rotation speed of 1 rpm. The prepared die attachment paste was applied to an upper portion of a wafer by means of screen printing. UV was irradiated to the paste applied to the wafer at 6.5 J/□ based on the UV A region, then the paste was thermally dried at 220° C. for 5 minutes, and then MT lamination was conducted thereto at a room temperature. The wafer used in the comparative example 2 was identical to that of the comparative example 1.

### Comparative Example 3

Liquid epoxy, solid epoxy, acrylic reactants, inorganic/organic filler, additives, thermal curing agent, thermal initiator, UV initiator, reactant solvent, and volatile solvent were mixed and made into a die attachment paste with a viscosity of 500 cps at a room temperature using a spindle with a rotation speed of 1 rpm. The prepared die attachment paste was applied to an upper portion of a wafer that is rotating by a spin coater. The paste applied to the wafer was thermally dried at 100° C. for 1 hour and 20 minutes, and then MT lamination was conducted thereto at a room temperature. The wafer used in the comparative example 3 was identical to that of the comparative example 1.

### Comparative Example 4

Liquid epoxy, solid epoxy, acrylic reactants, inorganic/organic filler, additives, thermal curing agent, thermal initiator, UV initiator, reactant solvent, and volatile solvent were mixed and made into a die attachment paste with a viscosity of 200,000 cps at a room temperature using a spindle with a rotation speed of 1 rpm. The prepared die attachment paste was applied to an upper portion of a wafer that is rotating by a spin coater. The paste applied to the wafer was thermally dried at 100° C. for 1 hour and 20 minutes, and then MT lamination was conducted thereto at a room temperature. The wafer used in the comparative example 4 was identical to that of the comparative example 1.

### Evaluation of Uniformity of Paste Thickness

In order to evaluate uniformity of thickness of the paste applied to a wafer in case the packaging methods according to the embodiments 1 to 3 and the comparative examples 1 to 4 were applied, a thickness of a middle portion of the applied paste was measured after B-staging, and a difference between a maximum thickness and the thickness of the middle portion was calculated.

### Evaluation of Die Pick-up Characteristics

In the die pick-up process, the die/paste was separated from a mount tape or a dicing tape after the sawing process. Assuming that the number of eject pins mounted in a pick-up M/C was fixed to 9 with a height of 500□ and the chip has a size of 1 cm×1 cm and a thickness of 200□, it was examined whether the mount tape and the paste are well separated after the pick-up process, whether paste impurities remain on the adhesive of the mount tape, and whether the die and the paste are separated. At this time, the used mount tape was SUS304 with an adhesive force in the level of 0.5 gf/in. and in the used die pick-up equipment, a pick-up time of a mounting tool was controlled to about 100 to 1000 msec. In this way, the die pick characteristics in case the packaging methods according to the embodiments 1 to 3 and the comparative examples 1 to 4 were applied were evaluated.

### Evaluation of Die Attachment Characteristics

The die attachment characteristics were evaluated using a process of attaching the picked-up die/paste onto AUS308 type (Solder Resist AUS308 type) PCB. At this time, die attachment pressure, temperature and time were controlled as process variables of the equipment; namely the temperature was controlled in the range from a room temperature to 200° C., the pressure was controlled in the range from 0.5 to 10 kgf, and the time was controlled in the range from 0.1 to 3 seconds. In this way, die attachment characteristics in case the packaging methods according to the embodiments 1 to 3 and the comparative examples 1 to 4 were applied were evaluated.

### Evaluation of MRT Characteristics

After die attachment, curing was conducted, and MRT (Moisture Resistance Test) was conducted. A curing process for full curing of liquid paste was conducted at 175° C. for 1 hour, and constant temperature and humidity conditions were 85° C., 60%, one week, JEDEC level 12. Also, reflow conditions for thermal shock were set as a Pb-free condition with a peak temperature of 250° C. The MRT is used for evaluating resistances against moisture and heat, which are requested to semiconductor package products. For this test, it is examined whether pop-corn phenomenon, die crack, or die delamination occurs between the die and the paste or between the paste and the PCB in a package product due to thermal shock after the reflow process. In this way, MRT characteristics in case the packaging methods according to the embodiments 1 to 3 and the comparative examples 1 to 4 were applied were evaluated.

The following table 1 shows evaluation results of thickness uniformity of paste, die pick-up characteristics, die attachment characteristics and MRT characteristics in the embodiments 1 to 3 and the comparative examples 1 to 4.

TABLE 1

| | Embodiments | | | Comparative Examples | | | |
|---|---|---|---|---|---|---|---|
| | 1 | 2 | 3 | 1 | 2 | 3 | 4 |
| Thickness of middle | 20 to | 20 to | 20 to | 20 to | 20 to | not more | 40 to 80□ not |
| portion of applied | 80□ | 80□ | 80□ | 80□ | 80□ | than 20□ | less than 40□ |
| paste after B- | | | | | | | |
| staging | | | | | | | |
| Difference between | less | less | less | less | less | less than | less than 20□ |
| max thickness and | than | than | than | than | than | 5□ | |
| middle portion | 5□ | 5□ | 5□ | 34□ | 34□ | | |
| thickness | | | | | | | |
| Die pick-up characteristic | good | good | good | bad | good | good | good |
| Die attachment characteristic | good | good | good | bad | bad | good | good |
| MRT characteristic | good | good | good | failed | failed | failed | failed |

The thickness of a middle portion of a paste applied after B-staging should be about 20□ or more according to the requirements of BOC products applied to DRAM package. It gives a room such that glass beads in an epoxy mold may be easily filled in a residual portion where paste is not present between a die and PCB during the EMC process, after wire bonding. That is to say, the paste should be applied with a greater thickness than a particle size of the glass beads. Seeing the table 1, it would be understood that the thickness of 20□ or above is not easily maintained if viscosity is too low. In addition, as explained above in the characteristic evaluation, MRT characteristics allows checking phenomena such as pop-corn, die crack, and die delamination, from which reliability may be determined. If all of tested samples have no inferiority, the test is considered as being successful.

From the results in the table 1, it would be understood that the embodiments 1 to 3 are much more excellent than the comparative examples 1 to 4 in aspect of uniformity of thickness, die pick-up characteristics, die attachment characteristics, and MRT characteristics.

### INDUSTRIAL APPLICABILITY

According to the semiconductor packaging method of the present invention, it is possible to reduce costs by substituting for WBL (Wafer Backside Lamination) film, uniformly apply a die attachment paste to a wafer, freely control a thickness of applied die attachment paste by adjusting viscosity and dosage of discharged paste and a speed f a spin coater, and also shorten a process time by decreasing a B-staging time.

1. A method for packaging a semiconductor, comprising:
preparing a die attachment paste with a viscosity of 1,500 to 100,000 cps;
rotating a wafer and applying the die attachment paste to an upper surface of the wafer into a predetermined thickness; and
B-staging the paste applied on the wafer.

2. The method for packaging a semiconductor according to claim 1, wherein the B-staging step includes thermally drying the applied paste at 40 to 200° C.

3. The method for packaging a semiconductor according to claim 2, wherein the B-staging step further includes irradiating ultraviolet (UV) in 100 mJ/cm² to 6 J/cm² based on a UV A region after the thermal drying step.

4. The method for packaging a semiconductor according to claim 3, wherein the B-staging step further includes thermally drying the wafer at 40 to 200° C. after the UV irradiating step.

5. The method for packaging a semiconductor according to claim 1, wherein the B-staging step includes irradiating UV to the applied paste in 100 mJ/cm² to 6 J/cm² based on a UV A region.

6. The method for packaging a semiconductor according to claim 5, wherein the B-staging step further includes thermally drying the paste at 40 to 200° C. after the UV irradiating step.
